(19) United States
(12) Patent Application Publication
(10) Pub. No.: US 2025/0081816 A1
(43) Pub. Date: Mar. 6, 2025

(54) DISPLAY DEVICE

(71) Applicant: LG Display Co., Ltd., Seoul (KR)

(72) Inventors: KyooHo LEE, Paju-si (KR); KyoungJin NAM, Paju-si (KR)

(73) Assignee: LG Display Co., Ltd., Seoul (KR)

(21) Appl. No.: 18/811,416

(22) Filed: Aug. 21, 2024

(30) Foreign Application Priority Data
Sep. 1, 2023 (KR) 10-2023-0115911

(51) Int. Cl. H10K 59/80; H10K 59/131

(52) U.S. Cl. CPC H10K 59/873; H10K 59/131

(57) ABSTRACT

A display device in one example includes a substrate having a display area allowing an image to be displayed and a non-display area located outside of the display area. The display device further includes a light emitting element disposed in the display area of the substrate, and an encapsulation layer on the light emitting element and extending into the non-display area. Further, the display device includes a first metal dam disposed in the non-display area and located further away from the display area than the encapsulation layer in the non-display area. This configuration enables a bezel area to be extremely reduced.

### CROSS-REFERENCE TO RELATED APPLICATION

This application claims priority to Korean Patent Application No. 10-2023-0115911, filed on Sep. 1, 2023 in the Korean Intellectual Property Office, the entire contents of which is hereby expressly incorporated by reference into the present application.

### BACKGROUND

### Field

The present disclosure relates to electronic devices with displays, and more specifically, to a display device with an extreme narrow bezel area.

### Discussion of the Related Art

A display panel included in a display device can include a display area allowing an image to be displayed and a non-display area where an image is not displayed. Various structures, circuits, and lines can be disposed in the non-display area (which can be also referred to as a bezel or a bezel area) of the display panel.

To meet high market demands for a large display area, it would be desirable to reduce the bezel of a display panel. However, since various elements such as the lines are located in the non-display area, challenges can arise in reducing the bezel of the display panel.

A structure where the bezel area is reduced to become almost zero (or very close to zero such as less than 1 mm) can be referred to as an extreme narrow bezel structure, and this can also be referred to as a zero bezel. There is a need to provide a display device with a zero bezel with improved configurations/structures.

### SUMMARY OF THE DISCLOSURE

In view of the above discussed needs associated with the related art and to address limitations associated with the related art, one or more aspects of the present disclosure can provide a display device having an extreme narrow bezel structure, which is light weight.

One or more aspects of the present disclosure can provide a display device having an organic material overflow prevention structure enabling the display device to be configured with an extreme narrow bezel.

One or more aspects of the present disclosure can provide a display device having a structure of surrounding an encapsulation layer using a metal dam.

One or more aspects of the present disclosure can provide a display device having an advantage of process optimization through reduction of the bezel area of a display panel.

According to example aspects of the present disclosure, a display device can be provided that includes a substrate including a display area allowing an image to be displayed and a non-display area located outside of the display area, a light emitting element disposed in the display area of the substrate, an encapsulation layer on the light emitting element, and a first metal dam including a first metal and located farther away from the display area than the encapsulation layer.

The display area can further include a second metal dam located adjacent to the first metal dam and including the first metal or a second metal.

According to example aspects of the present disclosure, a display device can be provided that includes a substrate including a display area allowing an image to be displayed and a non-display area located outside of the display area, a light emitting element disposed in the display area of the substrate, an encapsulation layer on the light emitting element, and a first voltage line including a first protrusion protruding to surround the encapsulation layer.

The display area can further include a first voltage line layer, a second voltage line layer disposed on the first voltage line layer, and a second protrusion disposed on the second voltage line layer. For example, the second protrusion can be located closer to the display area than the first protrusion.

According to one or more aspects of the present disclosure, an improved display device can be provided that has an extreme narrow bezel structure.

According to one or more aspects of the present disclosure, a display device can be provided that has an organic material overflow prevention structure enabling the display device to be configured with an extreme narrow bezel.

According to one or more aspects of the present disclosure, a display device can be provided that has a structure of surrounding an encapsulation layer using a metal dam.

According to one or more aspects of the present disclosure, a display device can be provided that is capable of being configured with light weight through reduction of the bezel area of a display panel.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to aspects of the present disclosure;

FIG. 2 illustrates an example display panel of the display device according to aspects of the present disclosure;

FIG. 3 illustrates an example substrate of the display panel according to aspects of the present disclosure;

FIGS. 4 and 5 are cross-sectional views illustrating an example first metal dam disposed in a non-display area of the display panel according to aspects of the present disclosure;

FIG. 6 is a cross-sectional view illustrating example first and second metal dams disposed in the non-display area of the display panel according to aspects of the present disclosure; and

FIG. 7 is a cross-sectional view illustrating an example first metal dam disposed in the non-display area of the display panel according to aspects of the present disclosure.

### DETAILED DESCRIPTION OF THE EMBODIMENTS

Reference will now be made in detail to embodiments of the present disclosure, examples of which can be illustrated in the accompanying drawings. In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting”, “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element is “connected to” or “coupled to”, “contacts” or “overlaps,” etc. a second element, it should be interpreted that, not only can the first element “be directly connected or coupled to” or “directly contact or overlap” the second element, but at least one third element or other elements can also be “interposed” between the first and second elements, or the first and second elements can “be connected or coupled to”, “contact or overlap”, etc. each other via at least one fourth element or other elements. Here, the second element can be included in at least one of two or more elements that “are connected or coupled to”, “contact or overlap”, etc. with each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various embodiments of the present disclosure will be described in detail. All the components of each display device according to all embodiments of the present disclosure are operatively coupled and configured. Further, the term “device” is interchangeably used with a term “apparatus” or the like.

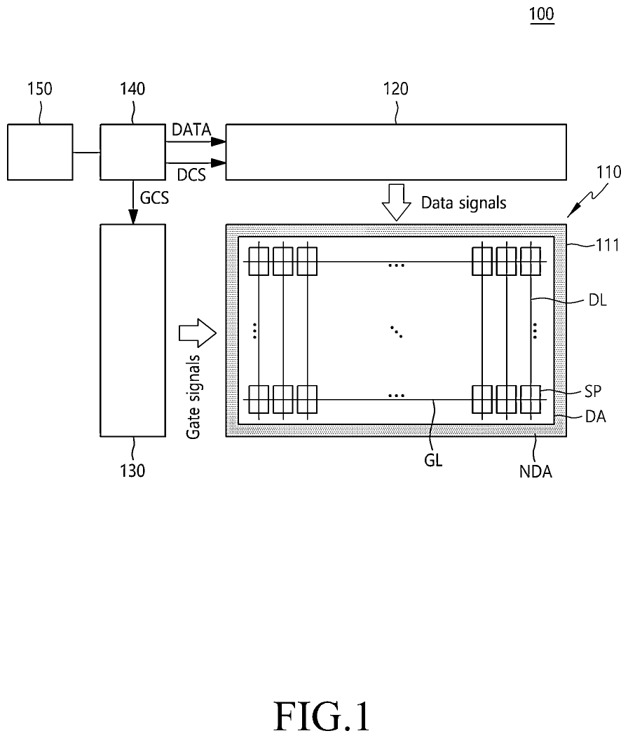

FIG. 1 illustrates an example system configuration of a display device 100 according to aspects of the present disclosure.

Referring to FIG. 1, in one or more example embodiments, the display device 100 can include a display panel 110 and a display driving circuit as components for displaying an image. The display driving circuit can include one or more of components, modules, circuits, elements, layers, structures, materials, etc. The display driving circuit can be a circuit for driving the display panel 110, and include a data driving circuit 120, a gate driving circuit 130, a display controller 140, and other circuit components or the like.

The display panel 110 can include a substrate 111 and a plurality of subpixels SP disposed on the substrate 111.

The substrate 111 of the display panel 110 can include a display area DA allowing an image to be displayed and a non-display area NDA located outside of the display area DA. The display area DA can also be referred to as an active area AA, whereas the non-display area NDA can also be referred to as a non-active area NAA. The non-display area NDA can completely surround the display area DA or can be adjacent to one or parts of the display area DA. Other variations are possible and part of the present disclosure.

The plurality of subpixels SP for displaying an image can be disposed in the display area DA, and the non-display area NDA can include a pad area PA located in a first direction from the display area DA. The subpixels SP can emit light of different colors such as red, green, blue, etc. Further, a subset of the subpixels SP can form a pixel or a pixel unit, where a plurality of pixels can be disposed in the display area DA.

In the display panel 110 according to aspects of the present disclosure, the non-display area NDA can have a very small area compared with the display area DA. Herein, the non-display area NDA can be also referred to as a “bezel” or a “bezel area.”

For example, the non-display area NDA can include a first non-display area located outside of the display area DA in a first direction, a second non-display area located outside of the display area DA in a second direction intersecting the first direction, a third non-display area located outside of the display area DA in a direction opposite to the first direction, and a fourth non-display area located outside of the display area DA in a direction opposite to the second direction. However, other variations are possible and part of the present disclosure.

In an example, one or two non-display areas among the first to fourth non-display areas can include a pad area to which the data driving circuit 120 is connected or bonded. In one or more aspects, among the first to fourth non-display areas, each of the remaining two or three non-display areas, which do not include the pad area, can have a very small size compared with the one or two non-display areas.

In one or more aspects, a boundary area between the display area DA and the non-display area NDA can be bent or curved, and thereby, the non-display area NDA can be located under or above the display area DA or can have an overlapping area with the display area DA. In this implementation, when a user views the display device 100 in front thereof, all or most of the non-display area NDA may not be visible to the user.

Various types of signal lines for driving the plurality of subpixels SP can be disposed on the substrate 111 of the display panel 110.

In one or more aspects, the display device 100 can be a liquid crystal display device, or the like, or a self-emission display device in which light is emitted from the display panel 110 itself. In an example where the display device 100 according to aspects of the present disclosure is the self-emission display device, each of the plurality of subpixels SP can include a light emitting element.

For example, the display device 100 according to aspects of the present disclosure can be an organic light emitting display device implemented with organic light emitting diodes (OLED) as light emitting elements. In another example, the display device 100 according to aspects of the present disclosure can be an inorganic light emitting display device implemented with inorganic material-based light emitting diodes as light emitting elements. In still another example, the display device 100 according to aspects of the present disclosure can be a quantum dot (QD) display device implemented with quantum dots, which are self-emission semiconductor crystals, as light emitting elements, or can be a display device with micro-LEDs.

The structure of each of the plurality of subpixels SP can depend on the types of display device 100. For example, if the display device 100 is a self-emission display device including self-emission subpixels SP, each subpixel SP can include a self-emission light emitting element, one or more transistors, and one or more capacitors.

The various types of signal lines can include, for example, a plurality of data lines DL for carrying data signals (which can be referred to as data voltages or image signals), a plurality of gate lines GL for carrying gate signals (which can be referred to as scan signals), and the like.

In one or more aspects, the plurality of data lines DL and the plurality of gate lines GL can intersect one another. Each of the plurality of data lines DL can be configured to extend in a first direction, and each of the plurality of gate lines GL can be configured to extend in a second direction. For example, the first direction can be a column or vertical direction, and the second direction can be a row or horizontal direction. In another example, the first direction can be the row or horizontal direction, and the second direction can be the column or vertical direction. The first and second directions can be perpendicular to each other, but can form a different angle with each other. Hereinafter, for convenience of explanation, discussions can be provided based on examples where each of the plurality of data lines DL is disposed in the column direction, and each of the plurality of gate lines GL is disposed in the row direction, but aspects of the present disclosure are limited thereto.

The data driving circuit 120 can be a circuit for driving the plurality of data lines DL and can output data signals to the plurality of data lines DL.

The data driving circuit 120 can receive image data DATA in digital form from the display controller 140, convert the received image data DATA into data signals in analog form, and output the converted data signals to the plurality of data lines DL.

In one or more aspects, the data driving circuit 120 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or implemented in the display panel 110 by a chip-on-film (COF) technique.

The data driving circuit 120 can be located in, and/or electrically connected to, but not limited to, only one side or portion (e.g., an upper edge or a lower edge) of the display panel 110. In one or more aspects, the data driving circuit 120 can be disposed in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or other design requirements. In the example, the display panel 110 can have a shape of a quadrilateral such as a rectangle, but can have other shapes.

The data driving circuit 120 can be connected to outside, or an edge, of the display area DA of the display panel 110, or be disposed in the display area DA of the display panel 110.

The gate driving circuit 130 can be a circuit for driving the plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 can be embedded into the display panel 110 by a gate-in-panel (GIP) technique. In an example where the gate driving circuit 130 is implemented by the gate-in-panel (GIP) technique, the gate driving circuit 130 can be disposed on the substrate 111 of the display panel 110 during the manufacturing process of the display panel 110 or display device 100.

In one aspect, the gate driving circuit 130 included in the display device 100 can be disposed in the display area DA of the display panel 110. In this implementation, for example, the gate driving circuit 130 can be disposed in, and/or electrically connected to, but not limited to, a first area (e.g., a left area or a right area) of the display area DA of the display panel 110. In another example, the gate driving circuit 130 can be disposed in, and/or electrically connected to, but not limited to, a first area (e.g., a left area or a right area) and a second area (e.g., the right area or the left area) of the display area DA of the display panel 110.

Herein, the gate driving circuit 130 embedded in the display panel 110 by the gate-in-panel (GIP) technique can also be referred to as a “gate-in-panel circuit.”

The display controller 140 can be a device for controlling the data driving circuit 120 and the gate driving circuit 130, and can control driving timing for the plurality of data lines DL and driving timing for the plurality of gate lines GL.

The display controller 140 can supply a data driving control signal DCS to the data driving circuit 120 to control the data driving circuit 120, and supply a gate driving control signal GCS to the gate driving circuit 130 to control the gate driving circuit 130.

The display controller 140 can receive image data input from a host system 150 and supply image data DATA readable by the data driving circuit 120 based on the input image data to the data driving circuit 120.

The display controller 140 can be implemented in a separate component from the data driving circuit 120, or can be incorporated in the data driving circuit 120 and thus implemented in an integrated circuit.

The display controller 140 can be a timing controller used in general display technology or a controller or a control device capable of performing other control functions in addition to the function of the general timing controller. In one or more embodiments, the display controller 140 can be a controller or a control device different from the timing controller, or a circuitry or a component included in the controller or the control device. The display controller 140 can be implemented using various circuits or electronic components such as an integrated circuit (IC), a field programmable gate array (FPGA), an application specific integrated circuit (ASIC), a processor, and/or the like.

The display controller 140 can be mounted on a printed circuit board, a flexible printed circuit, and/or the like and be electrically connected to the gate driving circuit 120 and the data driving circuit 130 through the printed circuit board, flexible printed circuit, and/or the like.

The display controller 140 can transmit signals to, and receive signals from, the data driving circuit 120 via one or more predefined interfaces. For example, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 can include a touch sensor, and a touch sensing circuit configured to sense the touch sensor and detect whether a touch is applied by an object such as a finger, a pen, or the like, or a location of the touch.

The touch sensing circuit can include a touch driving circuit configured to drive and sense the touch sensor and generate and output touch sensing data, and a touch controller capable of detecting whether a touch is applied or a location of the touch using the touch sensing data.

The touch sensor can include a plurality of touch electrodes. The touch sensor can further include a plurality of touch lines to electrically connect the plurality of touch electrodes to the touch driving circuit.

The touch sensor can be implemented in the form of a touch panel outside of the display panel 110 or be integrated inside of the display panel 110. In the example where the touch sensor is implemented in the form of the touch panel outside of the display panel 110, such a touch sensor can be referred to as an add-on type. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of the plurality of touch electrodes and generate touch sensing data by sensing at least one of the plurality of touch electrodes.

The touch sensing circuit can perform touch sensing by a self-capacitance sensing technique, a mutual-capacitance sensing technique or other known sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of the plurality of touch electrodes can serve as both a driving touch electrode and a sensing touch electrode. The touch driving circuit can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, the plurality of touch electrodes can be divided into driving touch electrodes and sensing touch electrodes. The touch driving circuit can drive the driving touch electrodes and sense the sensing touch electrodes.

In one or more aspects, the touch driving circuit and the touch controller included in the touch sensing circuit can be implemented in separate devices or in a single device. In one or more aspects, the touch driving circuit and the data driving circuit can be implemented in separate devices or in a single device.

The display device 100 can further include a power supply circuit for supplying various types of power to the display driving circuit and/or the touch sensing circuit.

In one or more aspects, the display device 100 can represent, but is not limited to, a mobile terminal, such as a smart phone, a tablet, or the like, a monitor, a television (TV), a screen, a laptop, a gaming device, a navigation device, a wearable device, a watch, or the like. Embodiments of the present disclosure are not limited thereto. In one or more aspects, the display device 100 can be display devices, or include displays, of various types, sizes, configurations, and shapes for displaying information or images.

In one or more example embodiments, the display device 100 can further include one or more electronic devices such as a camera (e.g., an image sensor), a sensor capable of detecting an object, and the like. For example, the sensor can be a sensor capable of detecting an object or a human body by receiving light such as infrared light, ultrasonic light, ultraviolet light or the like. As an example, the sensor can include one or more of a proximity sensor, an optical sensor, a biometric sensor or other types of sensors.

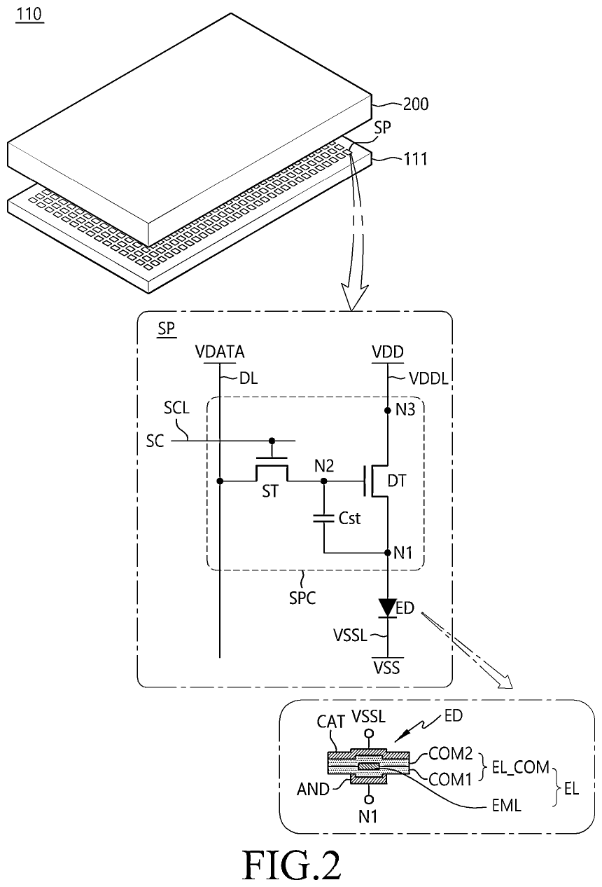

FIG. 2 illustrates an example configuration of the display panel 110 according to aspects of the present disclosure.

Referring to FIG. 2, in one or more example embodiments, the display panel 110 can include a substrate 111 on which the plurality of subpixels SP are disposed, and an encapsulation layer 200 over the substrate 111. The encapsulation layer 200 can also be referred to as an encapsulation substrate or a sealing element.

In this example where the display device 100 is a self-emission display device, each of the plurality of subpixels SP disposed on the substrate 111 can include a light emitting element ED and a subpixel circuit SPC for driving the light emitting element ED.

The subpixel circuit SPC can include a plurality of pixel driving transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of pixel driving transistors can include a driving transistor DT for driving the light emitting element ED and a scan transistor ST configured to be turned on or off by a scan signal SC.

The driving transistor DT can supply a driving current to the light emitting element ED. The scan transistor ST can be configured to control an electrical state of a corresponding node in the subpixel circuit SPC or to control the state or operation of the driving transistor DT.

The at least one capacitor can include a storage capacitor Cst configured to maintain a constant voltage during a display frame or a certain period of the display frame.

To drive one or more subpixels SP, a data signal VDATA, which is an image signal, and a scan signal SC, which is a gate signal, can be applied to the subpixel SP. Further, at least one common pixel driving voltage including a first common driving voltage VDD and a second common driving voltage VSS can be applied to the one or more subpixels SP.

The light emitting element ED can include an anode AND, a light emitting element intermediate layer EL, and a cathode CAT. The light emitting element intermediate layer EL can be disposed between the anode AND and the cathode CAT. However, other variations and configurations for the light emitting element ED are possible and part of the present disclosure.

In an example where the light emitting element ED is an organic light emitting diode, the light emitting element intermediate layer EL can include an emission layer EML, a first common intermediate layer COM1 between the anode AND and the emission layer EML, and a second common intermediate layer COM2 between the emission layer EML and the cathode CAT. The emission layer EML can be disposed in each subpixel SP. The first common intermediate layer COM1 and the second common intermediate layer COM2 can be commonly disposed across all or some of the plurality of subpixels SP The emission layer EML can be disposed in each subpixel SP, and the first common intermediate layer COM1 and the second common intermediate layer COM2 can be commonly disposed across the light emitting areas and non-light emitting areas of the plurality of subpixels SP. A layer including the first common intermediate layer COM1 and the second common intermediate layer COM2 can be referred to as a common intermediate layer EL_COM.

For example, the first common intermediate layer COM1 can include a hole injection layer (HIL), a hole transfer layer (HTL), and the like. The second common intermediate layer COM2 can include an electron transport layer (ETL), an electron injection layer (EIL), and the like. The hole injection layer (HIL) can inject holes from the anode AND to the hole transport layer (HTL), the hole transport layer (HTL) can transport holes to the emission layer EML, the electron injection layer (EIL) can inject electrons from the cathode CAT to the electron transport layer (ETL), and the electron transport layer (ETL) can transport electrons to the emission layer EML.

For example, the cathode CAT can be electrically connected to a second common driving voltage line VSSL. A second common driving voltage VSS, which is a type of common pixel driving voltage, can be applied to the cathode CAT through the second common driving voltage line VSSL. The anode AND can be electrically connected to a first node N1 of a corresponding driving transistor DT of each subpixel SP. Herein, the second common driving voltage VSS can also be referred to as a “base voltage”, and the second common driving voltage line VSSL can also be referred to as a “base voltage line.

For example, the anode AND can be a pixel electrode disposed in each subpixel SP, and the cathode CAT can be a common electrode commonly disposed in all or some of the plurality of subpixels SP. In another example, the cathode CAT can be a pixel electrode disposed in each subpixel SP, and the anode AND can be a common electrode commonly disposed in all or some of the plurality of subpixels SP. Hereinafter, for convenience of explanation, discussions can be provided based on examples where the anode AND is a pixel electrode, and the cathode CAT is a common electrode.

Each light emitting element ED can be configured by respective portions of the anode AND, the light emitting element intermediate layer EL, and the cathode CAT that overlap with each other. A corresponding light emitting area can be formed by each light emitting element ED. For example, the corresponding light emitting area of each light emitting element ED can include an area in which the anode AND, the light emitting element intermediate layer EL, and the cathode CAT overlap with each other.

In some aspects, the light emitting element ED can be an organic light emitting diode (OLED), an inorganic material-based light emitting diode (LED), or a quantum dot (QD) light emitting element. For example, when the light emitting element ED is an organic light emitting diode OLED, the light emitting element intermediate layer EL of this light emitting element ED can be a light emitting element intermediate layer including an organic material.

The driving transistor DT can be a transistor configured to supply a driving current to the light emitting element ED. The driving transistor DT can be connected between the first common driving voltage line VDDL and the light emitting element ED.

The driving transistor DT can include the first node N1 electrically connected with the light emitting element ED, a second node N2 to which the data signal VDATA is applied, and a third node N3 to which the driving voltage VDD through a driving voltage line DVL (e.g., the first common driving voltage line VDDL) is applied.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, embodiments of the present disclosure are not limited thereto.

The scan transistor ST included in the subpixel circuit SPC can be a switching transistor for allowing the data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL. The scan transistor ST can control an electrical connection between the second node N2 of the driving transistor DT and the corresponding data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

In one or more aspects, the storage capacitor Cst, which can be present between the first node N1 and the second node N2 of the driving transistor DT, can be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like).

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In an example where the display panel 110 has the bottom emission structure, the subpixel circuit SPC may not overlap the light emitting element ED in the vertical direction.

The subpixel circuit SPC can include two transistors (2T such as DT and ST) and one capacitor (1C such as Cst) (which can be referred to as a “2T1C structure”), and in some implementations, can further include one or more transistors, or further include one or more capacitors.

For example, the subpixel circuit SPC can have an 8T1C structure including 8 transistors and 1 capacitor. In another example, the subpixel circuit SPC can have an 6T2C structure including 6 transistors and 2 capacitor. In further another example, the subpixel circuit SPC can have an 7T1C structure including 7 transistors and 1 capacitor. Other variations are possible and part of the present disclosure.

The types and number of gate signals supplied to each subpixel SP, and/or the types and number of gate lines connected to each subpixel SP can vary depending on a structure of a corresponding subpixel circuit SPC.

Further, the types and number of common pixel driving voltages supplied to each subpixel SP can vary depending on a structure of a corresponding subpixel circuit SPC.

Since circuit elements (e.g., a light emitting element ED such as an organic light emitting diode (OLED) including an organic material) in each subpixel SP can be vulnerable to external moisture or oxygen, an encapsulation layer 200 can be disposed in the display panel 110 in order to prevent or minimize any external moisture or oxygen from penetrating into the circuit elements (e.g., the light emitting element ED). The encapsulation layer 200 can be disposed in various shapes or configurations to prevent or minimize the light emitting elements ED from contacting moisture, oxygen or other contaminants.

Meanwhile, the display device 100 according to aspects of the present disclosure can have an extremely narrow bezel structure in which the non-display area NDA (or bezel area) of the display panel 110 is very small or almost absent, which address the limitations associated with related art display devices.

Hereinafter, an extremely narrow bezel structure of the display panel 110 of a display device (e.g., the display device 100) according to aspects of the present disclosure will be described.

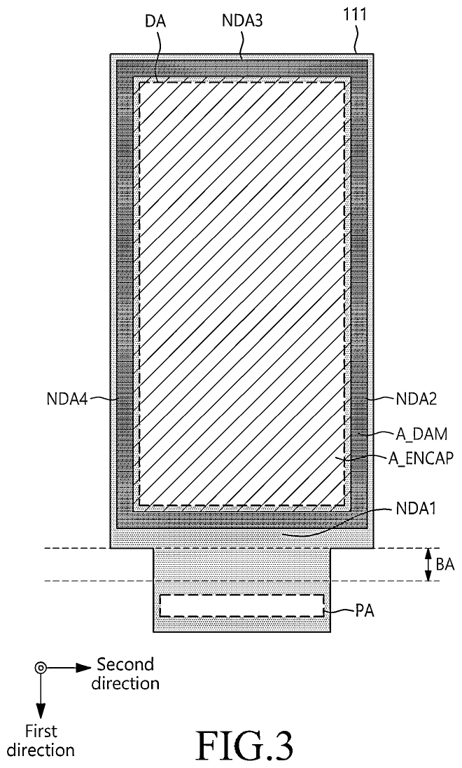

FIG. 3 illustrates an example substrate of the display panel 110 according to aspects of the present disclosure. In an example, the descriptions of various elements and configurations provided above in connection with FIGS. 1 and 2 can be equally applied here and can be part of the display panel 110 of FIG. 3.

Referring to FIG. 3, in one or more example embodiments, the substrate 111 of the display panel 110 can include a display area DA allowing an image to be displayed and a non-display area NDA in which an image is not displayed.

The non-display area NDA can include, for example, a first non-display area NDA1 located outside of the display area DA in a first direction, a second non-display area NDA2 located outside of the display area DA in a second direction, a third non-display area NDA3 located outside of the display area DA in a direction opposite to the first direction, and a fourth non-display area NDA4 located outside of the display area DA in a direction opposite to the second direction. For example, the first direction can be a column direction (e.g., a Y-axis direction), and the second direction intersecting the first direction can be a row direction (e.g., an X-axis direction).

The first non-display area NDA1 can include a pad area PA in which a plurality of pads are disposed.

One or more driving circuits can be electrically connected to one or more pads disposed in the pad area PA. A plurality of driving circuits or one or more printed circuit boards can be electrically connected to pads disposed in the pad area PA. For example, the plurality of pads can include a plurality of display pads and a plurality of touch pads. A plurality of data lines DL, a first common driving voltage line VDDL, a second common driving voltage line VSSL, and the like can be electrically connected to the plurality of display pads. A plurality of touch routing lines TL can be electrically connected to the plurality of touch pads.

In one or more example embodiments, the first non-display area NDA1 can further include a bending area BA. In this implementation, the substrate 111 can be a flexible substrate. In one or more aspects, the first non-display area NDA1 may not include a bending area BA. In another example, one or more of the non-display areas NDA1-NDA4 can include one or more bending areas BA.

The display panel 110 can further include a ground line disposed in the non-display area NDA of the substrate 111. The ground line can be disposed such that it runs from one point of the pad area PA to another point of the pad area PA via the second non-display area NDA2, the third non-display area NDA3, and the fourth non-display area NDA4.

The display panel 110 can include an encapsulation layer area A_ENCAP and a dam area A_DAM.

The encapsulation layer area A_ENCAP can be an area in which an encapsulation layer 200 is disposed. In one or more aspects, the encapsulation layer 200 included in the display panel 110 can have a structure in which at least one inorganic layer and at least one organic layer are stacked. In this implementation, an edge of the encapsulation layer 200 can be an edge of an organic layer included in the encapsulation layer 200.

The dam area A_DAM can be an area surrounding the encapsulation layer area A_ENCAP, e.g., entirely or in part. A structure functioning as a dam can be located in the dam area A_DAM. The dam can prevent an organic layer of a liquid state from flowing outwardly. The dam area A_DAM can be located in the non-display area NDA.

As the structure of a dam located in a dam area becomes larger, a bezel area, which is a non-display area, can become larger. Thus, the size of the bezel area can be reduced or impacted depending on the design of a dam structure located in the dam area.

Accordingly, one or more aspects of the present disclosure can provide the display device 100 having an extreme narrow bezel structure, which can effectively provide a zero or nearly zero bezel area.

Further, one or more aspects of the present disclosure can provide the display device 100 having an organic material overflow prevention structure enabling the display device 100 to be configured with an extreme narrow bezel.

Furthermore, one or more aspects of the present disclosure can provide the display device 100 having a structure of surrounding an encapsulation layer using a metal dam.

Moreover, one or more aspects of the present disclosure can provide the display device 100 capable of being configured with light weight through the reduction of the bezel area of the display panel 110.

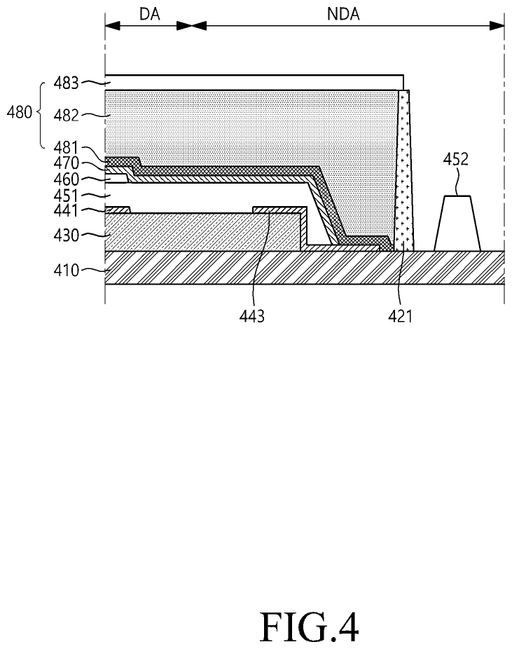

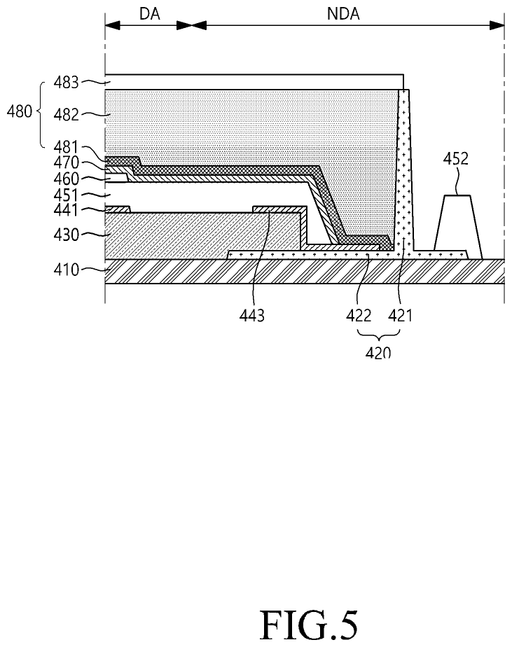

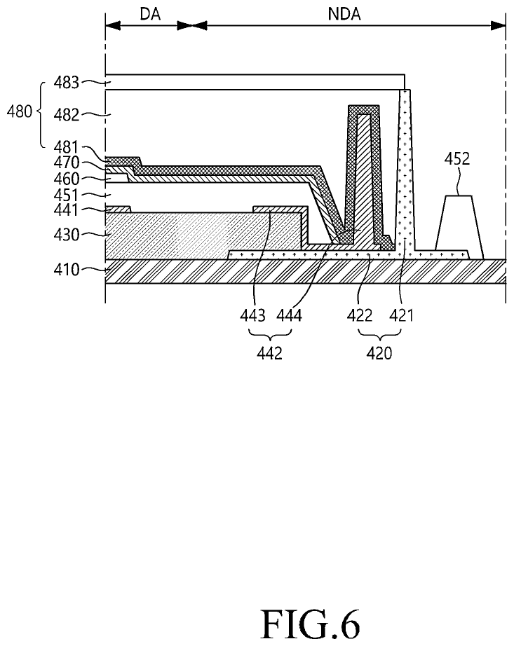

Particularly, FIGS. 4 and 5 are cross-sectional views illustrating an example first metal dam disposed in a non-display area of the display panel 110 according to aspects of the present disclosure. FIG. 6 is a cross-sectional view illustrating example first and second metal dams disposed in the non-display area of the display panel 110 according to aspects of the present disclosure. These figures show different examples of a cross-sectional view taking along an outer side portion of the display panel 110, which includes a portion of one display area DA and a portion of one non-display area (e.g., NDA1, NDA2, NDA3, or NDA4) immediately extending from that portion of the one display area DA. In one or more aspect of the present disclosure, the dam area A_DAM can be included in the non-display area NDA (or vice versa), and the encapsulation layer 200 can correspond to an encapsulation layer 480 to be discussed later.

Referring to two examples shown in FIGS. 4 and 5, in one or more example embodiments, the display panel 110 can include a panel lower layer 410, a first metal dam 421, a planarization layer 430, a pixel electrode 441, a connection electrode 443, a bank layer 451, a light emitting element intermediate layer 460, a common electrode 470, and the like.

The panel lower layer 410 can include a substrate, a transistor layer, and the like. The transistor layer can be disposed on the substrate. The transistor layer can include a gate electrode, a source electrode, a drain electrode, and a plurality of insulating layers. One or more planarization layers can be disposed on the transistor layer, and the transistor layer can be electrically connected to one or more other layers through one or more contact holes formed in the one or more planarization layers.

The planarization layer 430 can be disposed on the panel lower layer 410. The planarization layer 430 can be disposed in both the display area DA and the non-display area NDA. A portion of the planarization layer 430 corresponding to the display area DA can include at least one contact hole.

The pixel electrode 441 can be disposed on the planarization layer 430 in the display area DA. The pixel electrode 441 can be disposed such that it is patterned to be corresponded to an area of a subpixel, and is part of the subpixel. The pixel electrode 441 can be an anode electrode. A driving transistor included in the subpixel and an emission layer (e.g., which can be included in the light emitting element intermediate layer 460) can be electrically connected to each other through the pixel electrode 441.

The connection electrode 443 can be configured to cover a portion of the panel lower layer 410 and a portion of the planarization layer 430. The connection electrode 443 can be disposed in the non-display area NDA. The connection electrode 443 can be configured to cover the top surface of the panel lower layer 410, a side surface of the planarization layer 430, and the top surface of the planarization layer 430.

The connection electrode 443 can include, for example, the same material as the pixel electrode 441. In this example, the connection electrode 443 can be a portion resulting from patterning of the pixel electrode 441. For example, after a material of the pixel electrode 441 is deposited such that the material of the pixel electrode 441 covers the planarization layer 430 and a portion of the panel lower layer 410, then a portion of the disposed material of the pixel electrode 441 can be removed to form the pixel electrode 441 and the connection electrode 443 separated from the pixel electrode 441. Thus, the connection electrode 443 can be a remaining part separated from the pixel electrode 441. However, aspects of the present disclosure are not limited thereto. For example, the connection electrode 443 can be disposed through a separate process.

The bank layer 451 can be disposed on the planarization layer 430. The bank layer 451 can be a layer for defining a light emitting area of a subpixel. The bank layer 451 can be patterned so that a portion of the pixel electrode 441 and the light emitting element intermediate layer 460 can contact each other. For example, the bank layer 451 can be configured to cover both the planarization layer 430 and the pixel electrode 441. Thereafter, a portion corresponding to the light emitting area of the bank layer 451 can be removed. Since the portion corresponding to the light emitting area is removed from the bank layer 451, the light emitting element intermediate layer 460 located on the top of the bank layer 451 can contact the pixel electrode 441.

The light emitting element intermediate layer 460 can be disposed on the bank layer 451. Since the bank layer 451 is partially patterned, the light emitting element intermediate layer 460 on the bank layer 451 can be electrically connected to the pixel electrode 441. The light emitting element intermediate layer 460 can include a first common intermediate layer, an emission layer, and a second common intermediate layer, and the emission layer can be disposed at a location corresponding to the pixel electrode 441.

The common electrode 470 can be disposed on the light emitting element intermediate layer 460. The common electrode 470 can be a layer to which a base voltage is supplied. The common electrode 470 can be configured to contact the connection electrode 443, e.g., in the non-display area NDA. After the bank layer 451 is deposited such that it covers the connection electrode 443, the stack in which the bank layer 451 covers the connection electrode 443 can be patterned so that the common electrode 470 and the connection electrode 443 can contact each other.

By the patterning, a portion 452 of the bank layer 451 can be formed such that the portion 452 of the bank layer 451 remains on the panel lower layer 410 as shown in FIG. 4 or on a first protruding voltage line 420 as shown in FIG. 5, which will be discussed later in more detail.

After the patterning, the common electrode 470 can be disposed on the patterned bank layer 451. A portion of the bank layer 451 can be removed through a subsequent process. In this case, the first metal dam 421 can be placed at or adjacent to an outermost edge, which enables a zero bezel or an extreme narrow bezel to be implemented.

The encapsulation layer 480 can be disposed on the light emitting element intermediate layer 460 and the common electrode 470. The encapsulation layer 480 can include a first inorganic layer 481, an organic layer 482, and a second inorganic layer 483. The organic layer 482 can be disposed on the first inorganic layer 481, and the second inorganic layer 483 can be disposed on the organic layer 482.

The first inorganic layer 481 can be configured to cover the common electrode 470 and the connection electrode 443. The first inorganic layer 481 can also cover a portion of the substrate between an edge of the common electrode 43 and the first metal dam 421 in the non-display area NDA.

The organic layer 482 can be configured to cover the first inorganic layer 481, and can be disposed between the first and second inorganic layers 481 and 483. The organic layer 482 can be configured to contact the first metal dam 421. During the process of depositing encapsulation layer 480, the organic layer 482 can be in a liquid state. As the first metal dam 421 is disposed outside of the organic layer 482, the organic layer 482 in the liquid state can be prevented from flowing out.

The second inorganic layer 483 can be configured to cover the organic layer 482. The second inorganic layer 483 can be configured to cover a portion of the first metal dam 421. For instance, the second inorganic layer 483 can be configured to cover a portion of the top surface of the first metal dam 421. In one or more aspects, the second inorganic layer 483 can be configured to cover all of the first metal dam 421, e.g., the entire top surface of the first metal dam 421.

The first metal dam 421 can be located farther away from the display area DA than the encapsulation layer 480, and can include a first metal.

The first metal dam 421 can be disposed on the panel lower layer 410. The first metal dam 421 can be configured to contact the first inorganic layer 481, the organic layer 482, and the second inorganic layer 483.

As the first metal dam 421 is configured to contact an outer portion of the encapsulation layer 480, the organic layer 482 in the liquid state can be prevented from flowing out.

Now referring to another example of the display panel shown in FIG. 5, in addition to the structure of the display panel 110 shown in FIG. 4, the display panel 110 can further include a first voltage line layer 422.

The first voltage line layer 422 can be disposed on the panel lower layer 410. The first voltage line layer 422 can include a metal material. The first voltage line layer 422 can be disposed in the non-display area NDA. A plurality of voltage supply lines can be disposed in the non-display area NDA, and the first voltage line layer 422 can be any one of the plurality of voltage supply lines, or another type of line.

In one aspect, the first voltage line layer 422 can be configured to surround the display area DA entirely. In another aspect, the first voltage line layer 422 can be configured to surround only a portion of the display area DA. For example, referring to FIG. 2, the display area DA can include four sides (or side surfaces), and for example, the first voltage line layer 422 can be configured to surround all the four sides (or side surfaces) of the display area DA. In another example, the display area DA can include four sides (or side surfaces), and the first voltage line layer 422 can be configured to surround only one or more of the four sides (or side surfaces) of the display area DA.

Referring back to FIG. 5, a portion of the first voltage line layer 422 can extend under the encapsulation layer 480 and the planarization layer 430, so that it can be disposed between the panel lower layer 410 and the planarization layer 430. A portion of the planarization layer 430 corresponding to the non-display area NDA can be disposed on the first voltage line layer 422.

A portion of the first voltage line layer 422 can be configured to contact a portion of the connection electrode 443. The connection electrode 443 can be configured to cover the portion of the first voltage line layer 422 and a portion of the planarization layer 430.

The common electrode 470 can be configured to contact the connection electrode 443. Since the connection electrode 443 contacts the first voltage line layer 422, the common electrode 470 can be supplied with a voltage through the first voltage line layer 422 and the connection electrode 443. After the bank layer 451 is deposited such that the bank layer 451 covers the connection electrode 443 and the first voltage line layer 422, the stack in which the bank layer 451 covers the connection electrode 443 and the first voltage line layer 422 can be patterned so that the common electrode 470 and the connection electrode 443 can contact each other. By the patterning, the portion 452 of the bank layer 451 can be formed such that the portion 452 of the bank layer 451 remains on the first voltage line layer 422. After the patterning, the common electrode 470 can be disposed on the patterned bank layer 451. A portion of the bank layer 452 can be removed through a subsequent process. In this case, the first metal dam 421 can be placed at an outermost edge (e.g., of the encapsulation layer 480 and the common electrode 470), and this enables a zero bezel or an extreme narrow bezel to be implemented. In this situation, a portion of the first voltage line layer 422 can be removed along with a portion of the bank layer 452.

In the example of FIG. 5, the connection electrode 443 is present, but in one or more aspects, the connection electrode 443 may not be present. For instance, the connection electrode 443 may not be disposed in the non-display area NDA. In this implementation, the common electrode 470 can be configured to contact the first protruding voltage line 420, e.g., the first voltage line layer 422.

The first voltage line layer 422 and the first metal dam 421 can include metal. The first voltage line layer 422 and the first metal dam 421 can be part of the first protruding voltage line 420.

The first protruding voltage line 420 can be disposed on the panel lower layer 410. The first protruding voltage line 420 can include a flat part (e.g., the first voltage line layer 422) in the form of a line, and a protruding part (e.g., the first metal dam 421) in the form of a dam. For instance, the flat part 422 of the first protruding voltage line 420 can be the first voltage line layer 422. The protruding part 421 of the first protruding voltage line 420 can be the first metal dam 421. Thus, the first protruding voltage line 420 can include the first voltage line layer 422 and the first metal dam 421. The first voltage line layer 422 and the first metal dam 421 can be integrally formed as a single piece, thus forming the first protruding voltage line 420.

The first protruding voltage line 420 can be located further away from the display area DA than the encapsulation layer 480. For example, a part of the first protruding voltage line 420 located farther away from the display area DA than the encapsulation layer 480 can be the first metal dam 421. Thus, the first metal dam 421 can be located farther away from the display area DA than the encapsulation layer 480, and can include a first metal.

For example, the first protruding voltage line 420 can protrude to surround the encapsulation layer 480. A part of the first protruding voltage line 420 protruding to surround the encapsulation layer 480 can be the first metal dam 421. Thus, the first protruding voltage line 420 can include the first metal dam 421, which protrudes to surround the encapsulation layer 480, e.g., entirely or in part. For instance, the first metal dam 421 can protrude and extend along the four sides of the display panel 110 in the non-display areas NDA1-NDA4, so as to surround the entire encapsulation layer 480 extending throughout the display area DA and parts of the non-display areas NDA1-NDA4.

The first metal dam 421 can be disposed on the first voltage line layer 422 disposed in the non-display area NDA. The first metal dam 421 can be located on the first voltage line layer 422 and be integrally formed as a single piece with the first voltage line layer 422.

The first voltage line layer 422 can include a metal material. For example, the first voltage line layer 422 can include metal. In one aspect, since the first metal dam 421 can be integrally formed as a single piece with the first voltage line layer 422, the first metal dam 421 can include the same material as the first voltage line layer 422. In one aspect, the first voltage line layer 422 can include a first metal included in the first metal dam 421.

A width of the first metal dam 421 in FIG. 5 can be relatively less than a width of the first voltage line layer 422. Here, the width can be measured in the second direction shown in FIG. 3. For example, if the first voltage line layer 422 has a square shape with a relatively large width, the first metal dam 421 can also have a square shape, but a width of the first metal dam 421 can be relatively less than that of the first voltage line layer 422. Therefore, the first protruding voltage line 420 can have a shape in which a relatively narrow rectangular dam is disposed on the top of a relatively wide rectangular line. For example, the first metal dam 421, which is a protrusion of the first protruding voltage line 420, can have a structure capable of preventing the organic layer 482 from flowing out.

The bottom surface of the first metal dam 421 can contact a portion of the top surface of the first voltage line layer 422. For example, the first metal dam 421 can be disposed anywhere between both opposing side edges of the first voltage line layer 422 or in a middle portion of the first voltage line layer 422. For example, the middle portion of the first voltage line layer 422 can be a location based on the second direction shown in FIG. 3.

The first metal dam 421 can be configured to surround the encapsulation layer 480. For example, when the encapsulation layer 480 includes four sides (or side surfaces) to cover the entire display area DA and a part of the non-display areas NDA1-NDA4 extending therefrom, the first metal dam 421 can be configured to surround all of the four sides (or side ends) of the encapsulation layer 480. In this example, an inner side surface (e.g., the left side surface) of the first metal dam 421 can support an outer side (e.g., an outer side surface or the right side surface) of the encapsulation layer 480. In one aspect, the inner side surface (e.g., the left side surface) of the first metal dam 421 can contact the outer side (e.g., the outer side surface or the right side surface) of the encapsulation layer 480.

Referring now to FIGS. 4 and 5, in one aspect, at a location where the first metal dam 421 and the encapsulation layer 480 (e.g., the second inorganic layer 483) contact each other, an upper surface of the first metal dam 421 can be lower than an upper surface of the encapsulation layer 480 (e.g., the second inorganic layer 483). In this implementation, the upper surface of the encapsulation layer 480 can be on a same plane as the upper surface of the second inorganic layer 483. In one aspect, at a location where the first metal dam 421 and the organic layer 482 contact each other, the top surface of the first metal dam 421 can have a height greater than or equal to the top surface of at least one organic layer (e.g., the organic layer 482). For instance, the top surface of the first metal dam 421 can be at a same level or at a higher level than the the top surface of the organic layer 482 so that the organic layer 482 can be contained by the first metal dam 421. As a variation, the second inorganic layer 483 can be disposed so that the outer edge side surface and/or outer edge bottom side of the second inorganic layer 483 contacts the top surface and/or inner surface of the top portion of the first metal dam 421.

The first metal dam 421 can be configured to support a portion of the encapsulation layer 480. For example, when the encapsulation layer 480 includes four side surfaces to cover the display area DA and an adjacent portion of the non-display areas NDA, the first metal dam 421 can be configured to support three, or one or more, of such four side surfaces of the encapsulation layer 480. The first metal dam 421 can be configured to support the organic layer 482.

Since the first metal dam 421 is configured to surround an outer edge of the encapsulation layer 480, the organic layer 482 (e.g., an organic material included in the organic layer 482) included in the encapsulation layer 480 can be prevented from flowing out. Since the organic layer 482 can be supported only by the first metal dam 421, it is not necessary to form a separate dam (or additional dam) in the dam area A_DAM. Thus, since a separate dam is not needed in the present examples, the bezel area can be effectively reduced.

Referring now to another example of the display panel shown in FIG. 6, in addition to the structure of the display panel 110 shown in FIG. 5, the display panel 110 can further include a second metal dam 444.

The second metal dam 444 can include the first metal or a second metal different from the first metal.

The second metal dam 444 can be located adjacent to the first metal dam 421. The second metal dam 444 can be located closer to the display area DA than the first metal dam 421. Thus, the first metal dam 421 can be located outside of the second metal dam 444.

The second metal dam 444 can be located closer to the display area than the first metal dam 421 (e.g., on the left side of the first metal dam 421).

The connection electrode 443 and the second metal dam 444 can include metal. The connection electrode 443 and the second metal dam 444 can be included in and be part of a second protruding voltage line 442. The connection electrode 443 can be also referred to as a second voltage line layer 443.

The second protruding voltage line 442 can include a flat part (e.g., the second voltage line layer 443) in the form of a wire or line, and a protruding part (e.g., the second metal dam 444) in the form of a dam. The flat part of the second protruding voltage line 442 can be the second voltage line layer 443. The protruding part of the second protruding voltage line 442 can be the second metal dam 444. Thus, the second protruding voltage line 442 can include the second voltage line layer 443 and the second metal dam 444. The second voltage line layer 443 and the second metal dam 444 can be integrally formed as a single piece, thus forming the second protruding voltage line 442.

A width of the second metal dam 444 can be relatively less than a width of the second voltage line layer 443. Here, the width can be measured in the second direction shown in FIG. 3. For example, as shown in FIG. 6, when the second voltage line layer 443 has a square shape with a relatively large width, the second metal dam 444 can also have a square shape, but a width of the second metal dam 444 can be relatively less than that of the second voltage line layer 443. Therefore, the second protruding voltage line 442 can have a shape in which a relatively narrow rectangular dam is disposed on the top of a relatively wide rectangular line. For example, the second metal dam 444, which is the protrusion of the second protruding voltage line 442, can have a structure capable of preventing the organic layer 482 from flowing out. However, a portion of the organic layer 482 (e.g., some of liquid organic material) in the liquid state can flow past the second metal dam 444, and in this situation, the first metal dam 421 can serve to fully prevent the remaining portion of the liquid organic material of the organic layer 482 from flowing out.

The second protruding voltage line 442 can be configured to be covered by the encapsulation layer 480. The second protruding voltage line 442 can be configured to be covered by the first inorganic layer 481 included in the encapsulation layer 480. The first inorganic layer 481 can be configured to cover the common electrode 470, the second voltage line layer 443, and the second metal dam 444. Since the first inorganic layer 481 is configured to cover the second metal dam 444, a portion of the first inorganic layer 481 can be disposed in a protruding form to correspond with the protruding form of the second metal dam 444.

An upper surface of the second metal dam 444 can be lower than an upper surface of the encapsulation layer 480. For instance, the upper surface of the second metal dam 444 can be lower than an upper surface of the second inorganic layer 483 or the organic layer 482.

In one aspect, the organic layer 482 can be disposed between the second metal dam 444 (e.g., an upper surface of the second metal dam 444) and the second inorganic layer 483 (e.g., a lower surface of the second inorganic layer 483). In one aspect, the second metal dam 444 (e.g., an upper surface of the second metal dam 444) can be configured to contact the second inorganic layer 483 (e.g., a lower surface of the second inorganic layer 483).

The encapsulation layer 480 can be interposed between the second metal dam 444 and the first metal dam 421. For example, when or if the organic layer 482 (i.e., a part of the organic material included in the organic layer 482) does not flow past the second metal dam 444, the organic layer 482 may not be needed to be interposed between the second metal dam 444 and the first metal dam 421. In such a case, for instance, the organic layer 482 may be fully contained by the second metal dam 444, and may not need to be present between the first and second metal dams 421 and 444. In another example, when or if the organic layer 482 (i.e., a part of organic material included in the organic layer 482) flows past the second metal dam 444, the organic layer 482 can be interposed between the second metal dam 444 and the first metal dam 421.

The second metal dam 444 can be configured to contact the first inorganic layer 481. The second metal dam 444 can be configured to be spaced apart from the second inorganic layer 483. In the example of FIG. 6, a lower portion of the second metal dam 444 can be configured to contact the first inorganic layer 481. An upper portion of the second metal dam 444 can be configured to contact the organic layer 482, and the upper portion of the second metal dam 444 can be configured to be spaced apart from the second inorganic layer 483.

The first metal dam 421 can be configured to contact the organic layer 482. The first metal dam 421 can be configured to contact at least a portion of the second inorganic layer 483.

The second voltage line layer 443 can be disposed on the first voltage line layer 422. The first voltage line layer 422 and the second voltage line layer 443 can be disposed in the non-display area NDA.

The second voltage line layer 443 can include at least one metal among one or more metals included in the pixel electrode 441. The second metal dam 444 and the second voltage line layer 443 can include the same metal material. The second metal dam 444 can include at least one metal among one or more metals included in the pixel electrode 441.

The first voltage line layer 422 can include the same first metal as the first metal dam 421. The second voltage line layer 443 can include the same first metal or second metal as the second metal dam 444

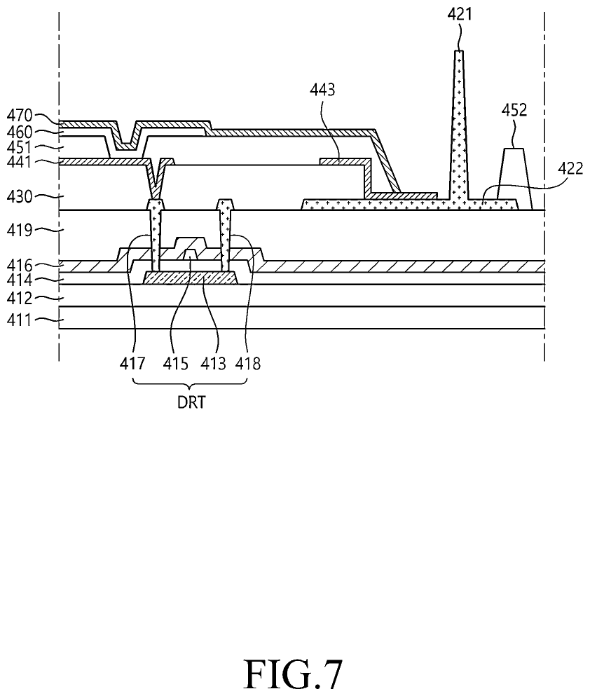

FIG. 7 is a cross-sectional view illustrating an example first metal dam disposed in the non-display area NDA of the display panel 110 according to aspects of the present disclosure. Particularly, FIG. 7 illustrates one example of the panel lower layer 410 shown in FIG. 5; however, the configuration of the panel lower layer 410 can be applied in the other display panel 110 of FIGS. 4 and 6.

Referring to FIG. 7, the panel lower layer 410 can include a substrate 411, a buffer layer 412, an active layer 413, a first insulating layer 414, a gate electrode 415, a source electrode 417, a drain electrode 418, a second insulating layer 416, and a second planarization layer 419.

The substrate 411 can be a layer located at the bottom of the display panel 110.

The buffer layer 412 can be disposed on the substrate 411. The buffer layer 412 can be a layer for electrically insulating between layers contacting the top and bottom of the buffer layer 412.

The active layer 413 can be disposed on the buffer layer 412. The active layer 413 can be a layer through which a driving current flows. The active layer 413 can be a metal layer.

The first insulating layer 414 can be disposed on the active layer 413 and the buffer layer 412. The first insulating layer 414 can be a layer for electrically insulating between layers contacting the top and bottom of the first insulating layer 414.

The gate electrode 415 can be disposed on the first insulating layer 414 and the active layer 413. The gate electrode 415 can be disposed on the first insulating layer 414 and be configured to overlap with a portion of the active layer 413.

The second insulating layer 416 can be disposed on the gate electrode 415 and the first insulating layer 414. The second insulating layer 416 can be a layer for electrically insulating between layers contacting the top and bottom of the second insulating layer 416.

The second planarization layer 419 can be disposed on the second insulating layer 416. The second planarization layer 419 can be disposed for electrical insulation and can also be disposed to maintain uniformity in height between layers. The second planarization layer 419 can include a contact hole. FIG. 7 illustrates one planarization layer, which is the second planarization layer 419, but aspects of the present disclosure are not limited thereto. For example, a third planarization layer and a fourth planarization layer can be additionally disposed on the second planarization layer 419 depending on design or other needs or preference. In this implementation, contact holes can be formed in the third planarization layer and the fourth planarization layer.

The source electrode 417 and the drain electrode 418 can be configured to penetrate the first insulating layer 414, the second insulating layer 416, and the second planarization layer 419. Contact holes can be formed in the first insulating layer 414, the second insulating layer 416, and the second planarization layer 419. The source electrode 417 and the drain electrode 418 can be configured to contact the active layer 413 through the contact holes.

A driving transistor DRT can include the active layer 413, the gate electrode 415, the source electrode 417, and the drain electrode 418. The driving transistor DRT can be configured to enable a driving current corresponding to a data voltage supplied to the gate electrode 415 to flow through the active layer 413. The driving current can flow to the pixel electrode 441 electrically connected to the source electrode 417. When the driving current is supplied to the pixel electrode 441 in the display area DA, light can be emitted by the light emitting element ED. The driving transistor DRT is disposed in the display area DA.

The first metal dam 421 can include the same material as the source electrode 417 or drain electrode 418 of the driving transistor DRT, or include the same material as a connecting electrode interconnecting between the source electrode 417 or drain electrode 418 of the driving transistor DRT and the pixel electrode 441.

As discussed in reference to FIGS. 1-7, the display panel or display device of the present application provides the structural configuration which allows a zero bezel area or an extreme narrow bezel area, which is advantageous and desirable with wide applications.

For instance, in the examples of FIGS. 4 and 5, since the first metal dam 421 is disposed outside of the encapsulation layer 480, the (liquid) organic layer 482 can be prevented from flowing outward, thus enabling an extreme narrow or zero bezel to be realized in the display device 100.

In the example of FIG. 6, since the first metal dam 421 is disposed outside of the encapsulation layer 480 and the second metal dam 444 is disposed inside of the encapsulation layer 480, the liquid organic layer 482 can be prevented from flowing out, thus enabling an extreme narrow or zero bezel to be realized in the display device 100.

The example embodiments of the present disclosure described above will be briefly described as follows.

According to the aspects described herein, the display device can be provided that includes a substrate including a display area allowing an image to be displayed and a non-display area located outside of the display area, a light emitting element disposed in the display area of the substrate, an encapsulation layer on the light emitting element, and a first metal dam including a first metal and located further away from the display area than the encapsulation layer.

The display device can further include a panel lower layer comprising the substrate and disposed under the light emitting element, and the first metal dam can be disposed on the panel lower layer.

The display device can further include a voltage line layer disposed in the non-display area, and the voltage line layer can include the first metal included in the first metal dam.

The first metal dam can be disposed on the voltage line layer. An inner side surface of the first metal dam can support an outer side surface of the encapsulation layer.

At a location where the first metal dam and the encapsulation layer contact, an upper surface of the first metal dam can be lower than an upper surface of the encapsulation layer.

The display device can further include a transistor for driving the light emitting element. The light emitting element can include a pixel electrode and a common electrode on the pixel electrode, the first metal dam can include a same material as a source electrode or a drain electrode of the transistor, or a same material as a connection electrode interconnecting between the source or drain electrode of the transistor and the pixel electrode.

The display device can further include a second metal dam adjacent to the first metal dam and including the first metal or a second metal different from the first metal. The second metal dam can be located closer to the display area than the first dam.

An upper surface of the second metal dam can be lower than an upper surface of the encapsulation layer. The second metal dam can be configured to be covered by the encapsulation layer, and the encapsulation layer can be interposed between the second metal dam and the first metal dam.

The display device can further include a first voltage line layer on the substrate, and a second voltage line layer on the first voltage line layer. The first and second voltage line layers can be disposed in the non-display area, the first voltage line layer can include the same first metal as the first metal dam, and the second voltage line layer can include the same first or second metal as the second metal dam.

The light emitting element can include a pixel electrode and a common electrode on the pixel electrode, and the second metal dam can include at least one metal included in the pixel electrode.

The encapsulation layer can include a first inorganic layer, an organic layer on the first inorganic layer, and a second inorganic layer on the organic layer. The second metal dam can be configured to contact the first inorganic layer, and the first metal dam can be configured to contact the organic layer.

The first metal dam can be configured to contact at least a portion of the second inorganic layer, and the second metal dam can be configured to be spaced apart from the second inorganic layer.

According to the aspects described herein, the display device can be provided that includes a substrate including a display area allowing an image to be displayed and a non-display area located outside of the display area, a light emitting element disposed in the display area of the substrate, an encapsulation layer on the light emitting element, and a first voltage line including a first protrusion protruding to surround the encapsulation layer.

At a location where the first protrusion and the encapsulation layer contact, an upper surface of the first protrusion can be lower than an upper surface of the encapsulation layer.

The first protruding voltage line can further include a first voltage line layer underneath the first protrusion.

The display device can further include a second voltage line layer disposed on the first voltage line layer, and a second protrusion disposed on the second voltage line layer. The second protrusion can be located closer to the display area than the first protrusion.

The second protrusion can be configured to be covered by the encapsulation layer, and the encapsulation layer can be interposed between the first protrusion and the second protrusion.

The encapsulation layer can include a first inorganic layer, an organic layer on the first inorganic layer, and a second inorganic layer on the organic layer. The second protrusion can be configured to contact the first inorganic layer, and the first protrusion can be configured to contact the organic layer.

The display device can further include a bank layer disposed between the substrate and the light emitting element, and a portion of the bank layer can be disposed outside of the first metal dam.

The portion of the bank layer can be disposed on the voltage line layer contacting a bottom surface of the first metal dam.

The first metal dam can be integrally formed as a single piece with the voltage line layer. The second metal dam can be integrally formed as a single piece with the second voltage line layer.

According to the aspects described herein, the display device can include a substrate comprising a display area configured to display an image and a non-display area disposed adjacent to the display area; an encapsulation layer covering the display area and a portion of the non-display area, the encapsulating layer including an organic layer; a first metal dam disposed in the non-display area, and configured to contain and surround the organic layer in the non-display area; and a second metal dam in the non-display area and being located closer to the display area than the first metal dam in the non-display area.

The display device can further comprise a bank layer disposed in the display area and the non-display area, and including at least two bank portions that are spaced apart from each other to define a space therebetween in the non-display area, wherein the first and second metal dams are disposed and protrude in the space between the at least two bank portions.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display device comprising:
a substrate comprising a display area allowing an image to be displayed and a non-display area located outside of the display area;
a light emitting element disposed in the display area of the substrate;
an encapsulation layer on the light emitting element; and
a first metal dam comprising a first metal and located further away from the display area than the encapsulation layer.

2. The display device of claim 1, further comprising:
a panel lower layer comprising the substrate and disposed under the light emitting element,
wherein the first metal dam is disposed on the panel lower layer.

3. The display device of claim 2, further comprising:
a voltage line layer disposed in the non-display area,
wherein the voltage line layer comprises the first metal included in the first metal dam.

4. The display device of claim 2, wherein the first metal dam is disposed on the voltage line layer.

5. The display device of claim 1, wherein an inner side surface of the first metal dam supports an outer side surface of the encapsulation layer.

6. The display device of claim 1, wherein at a location where the first metal dam and the encapsulation layer contact, an upper surface of the first metal dam is lower than an upper surface of the encapsulation layer.

7. The display device of claim 1, further comprising:
a transistor for driving the light emitting element,
wherein the light emitting element comprises a pixel electrode and a common electrode on the pixel electrode, and
wherein the first metal dam comprises a same material as a source electrode or a drain electrode of the transistor, or a same material as a connection electrode interconnecting between the source or drain electrode of the transistor and the pixel electrode.

8. The display device of claim 1, further comprising:
a second metal dam adjacent to the first metal dam and comprising the first metal or a second metal different from the first metal,
wherein the second metal dam is located closer to the display area than the first dam.

9. The display device of claim 8, wherein an upper surface of the second metal dam is lower than an upper surface of the encapsulation layer.

10. The display device of claim 8, wherein the second metal dam is configured to be covered by the encapsulation layer, and the encapsulation layer is interposed between the second metal dam and the first metal dam.

11. The display device of claim 8, further comprising:
a first voltage line layer on the substrate; and
a second voltage line layer on the first voltage line layer,
wherein: the first and second voltage line layers are disposed in the non-display area;
the first voltage line layer comprises the same first metal as the first metal dam; and
the second voltage line layer comprises the same first or second metal as the second metal dam.

12. The display device of claim 8, wherein the light emitting element comprises a pixel electrode and a common electrode on the pixel electrode, and
wherein the second metal dam comprises at least one metal included in the pixel electrode.

13. The display device of claim 8, wherein the encapsulation layer comprises:
a first inorganic layer;
an organic layer on the first inorganic layer; and
a second inorganic layer on the organic layer,
wherein the second metal dam is configured to contact the first inorganic layer, and the first metal dam is configured to contact the organic layer.

14. The display device of claim 13, wherein the first metal dam is configured to contact at least a portion of the second inorganic layer, and the second metal dam is configured to be spaced apart from the second inorganic layer.

15. A display device comprising:
a substrate comprising a display area allowing an image to be displayed and a non-display area located outside of the display area;
a light emitting element disposed in the display area of the substrate;
an encapsulation layer on the light emitting element; and
a first protruding voltage line comprising a first protrusion protruding to surround the encapsulation layer.

16. The display device of claim 15, wherein at a location where the first protrusion and the encapsulation layer contact, an upper surface of the first protrusion is lower than an upper surface of the encapsulation layer.

17. The display device of claim 15, wherein the first protruding voltage line further comprises a first voltage line layer underneath the first protrusion.

18. The display device of claim 17, further comprising:
a second voltage line layer disposed on the first voltage line layer; and
a second protrusion disposed on the second voltage line layer,
wherein the second protrusion is located closer to the display area than the first protrusion.

19. The display device of claim 18, wherein the second protrusion is configured to be covered by the encapsulation layer, and the encapsulation layer is interposed between the first protrusion and the second protrusion.

20. The display device of claim 18, wherein the encapsulation layer comprises:
a first inorganic layer;
an organic layer on the first inorganic layer; and
a second inorganic layer on the organic layer,
wherein the second protrusion is configured to contact the first inorganic layer, and the first protrusion is configured to contact the organic layer.

21. The display device of claim 3, further comprising:
a bank layer disposed between the substrate and the light emitting element,
wherein a portion of the bank layer is disposed outside of the first metal dam.

22. The display device of claim 21, wherein the portion of the bank layer is disposed on the voltage line layer contacting a bottom surface of the first metal dam.

23. The display device of claim 3, wherein the first metal dam is integrally formed as a single piece with the voltage line layer.

24. The display device of claim 11, wherein the second metal dam is integrally formed as a single piece with the second voltage line layer.
